(19) United States
(12) Patent Application Publication
(10) Pub. No.: US 2019/0329252 A1
(43) Pub. Date: Oct. 31, 2019

(54) MICROFLUIDIC CELL AND METHOD FOR THE PRODUCTION THEREOF

(71) Applicant: SCHOTT AG, Mainz (DE)

(72) Inventors: Hauke Esemann, Woerrstadt (DE); Stephanie Mangold, Klein - Winternheim (DE); Andreas Roters, Mainz (DE); Andreas Ortner, Gau-Algesheim (DE); Markus Heiss-Chouquet, Bischofsheim (DE); Fabian Wagner, Mainz (DE); Vanessa Hiller, Mainz (DE); Laura Brueckbauer, Dorn-Duerkheim (DE)

(73) Assignee: SCHOTT AG, Mainz (DE)

(21) Appl. No.: 16/396,291

(22) Filed: Apr. 26, 2019

(30) Foreign Application Priority Data
Apr. 27, 2018 (DE) 10 2018 110 210.0

(51) Int. Cl. B01L 3/00; B81C 1/00

(52) U.S. Cl. CPC B01L 3/502715; B81C 1/00047; B01L 2300/12; B81C 2203/0172; B01L 2200/0689; B81C 1/00119

(57) ABSTRACT

A method for the production of microfluidic cells using a disc-shaped glass element is provided. The disc-shaped glass element has a thickness of at most 700 micrometers is structured in such a way that it has at least one opening. The opening connects the two opposite-lying, parallel side faces of the glass element. The side faces are attached to a glass part so that the opening is sealed by the two glass parts to form a microfluidic cell having a cavity enclosed therein. The cavity is suitable for the conveyance of fluids. The attachment of the glass element to at least one of the two glass parts is produced by an adhesive that is applied onto the side face of the glass element. During application of the adhesive, the at least one opening in the glass element is left free of adhesive.

### CROSS REFERENCE TO RELATED APPLICATIONS

This application claims benefit under 35 USC § 119 of German Application 10 2018 110 210.0 filed Apr. 27, 2018, the entire contents of which are incorporated herein by reference.

### BACKGROUND

### 1. Field of the Invention

The invention relates to microfluidic cells, in general, as they are utilized for various tasks in analysis. In particular, the invention relates to a microfluidic cell made of glass.

### 2. Description of Related Art

The microfluidic cell in the sense of a “lab on a chip” system is an instrument for biochemical and medical analysis that is finding ever further distribution and application. Through molecule-specific reactions of added substances with biological molecules and systems introduced into the interior of the microfluidic cell, it is possible by means of optical sensors to accomplish tasks from the identification of molecules to DNA sequencing.

The simplest presentation of a microfluidic cell is accomplished through the combination of a bottom part, which is structured with channels, and a cover, which has access ports for the channels. In the current prior art, they are made of polymers by the injection molding method, for example. Corresponding arrangements are known, for example, from EP 2 719 460 B1 and DE 10 2011 085 371 A1.

The production of a microfluidic cell made of two polymeric components entails several drawbacks.

Polymers are often not resistant to the solvents used or lead to nonspecific reactions with introduced biological molecules (biocompatibility).

The auto-fluorescence as well as the limited transparency of the polymers influences or interferes with the read-out quality during detection of fluorescence-labelled substances.

In addition, the polymer surface offers only limited access to a functionalization with biomarkers.

As one solution approach to this, it has already been proposed to produce a microfluidic cell from three components, with the bottom and top components composed of glass and thus enabling a large field of functionalization. In addition, the channel structure is created using an organic polymeric component or a silicone component, which, for example, is attached to the top part and bottom part by means of an adhesive that is already applied before the structuring. A polymeric component is described in EP 2 547 618 B1 and elements made of silicone are described in the publications JP 2013 188677 A2 and CN 103992948 B. Further known from EP 3037826 A1 is a microfluidic cell that has a sandwich made of an elastomer layer between two glass substrates. The attachment occurs, for example, through direct bonding of the surfaces, which are activated by means of corona discharge. EP 3088076 A1 also describes multilayer cells in which the channel structures are inserted into silicone layers.

However, the combination of the material made of glass and the polymeric material has the drawback that, during analysis, the different expansion coefficients of the components, which go through various temperature cycles, can result in a deformation and, in the extreme case, in a lack of leaktightness of the cells. In addition, the problems of biocompatibility and auto-fluorescence are not solved by this approach.

Beyond this, in the case of an intermediate layer made of plastics material, there is the problem that, owing to the lack of stiffness of the plastics material, the often very thin and long channel structures can be adjusted to the structures of the top part and bottom part only inadequately when the two parts are joined together. Because a cost-effective production is made possible only by the fabrication of large substrates with, at the same time, a plurality of cells, the adjustment problem is further aggravated.

It would be possible to assemble a special microfluidic cell from three glass components. However, this necessitates a time-intensive and costly structuring process.

Further known from US 2008219890 A is a microfluidic cell that is composed of two components joined to each other using a layer of adhesive. However, in this case, a component, once it is made of glass, has to be structured in part through a complicated photomasking and etching process.

Known from the prior art are various structuring processes for glass. On the one hand, it is possible to introduce structures into glass by way of etching processes. Used for this purpose is a preceding masking process that protects the glass parts that are not to be etched. In addition, it is also possible to modify glasses by preferential etching. This is the case, for example, when a photo-structurable glass marketed under the trade name “Foturan” is used.

On the other hand, in recent years, laser-based structuring processes have also been utilized. Known for this purpose are the method of ablation as well as the method of filamentation.

Important criteria in the selection of a suitable structuring process are the ensuing costs for processing as well as the resistance to breakage of the glass component that is obtained.

As bonding methods for the production of microfluidic cells, the person skilled in the art knows, in addition to the high-temperature bonding process described in U.S. Pat. No. 9,446,378 B, for example, also the anodic bonding method, the direct bonding method (described, for example, in EP 3088076 A1), and the laser bonding method (such as described, for instance, in U.S. Pat. No. 9,517,929 B). These bonding methods share in common the drawback that they place high demands on the glass substrates that are to be bonded. These glass substrates must have a high planarity of the surfaces and a low thickness tolerance in order to enable the production of a completely closed channel structure. Moreover, the surface has to be completely free of particles down to the single digit μm range. These production processes thus do not allow an economical fabrication in high unit numbers. A further drawback of high-temperature bonding, for example, is that the cells can be furnished with biomarkers only after the parts are joined together.

### SUMMARY

The invention is based on the object of providing a microfluidic cell that is improved over the prior art in regard to the drawbacks set forth above. In particular, it should be possible to produce the cell as free of plastics as possible and more simply when compared to previous cells made of glass.

The solution to the challenges mentioned above is brought about in accordance with this invention in that a microfluidic cell is produced from three glass components, with the middle component (referred to herein as an interposer) composed of a structured thin glass and being bonded to a cover and a bottom by means of an adhesive that is applied on both sides after the structuring. All three components are thus made of an inert, non-fluorescing, and readily functionalized material. Stresses due to thermal expansions of different magnitude do not occur. Through the use of the adhesive technique, it is easily possible to ensure that the cells are leaktight. Through application of the adhesive onto the structured component, it is possible to furnish the surfaces of both the bottom and the cover that face the cell with biomarkers in an individual and full-surface manner prior to joining the components together.

Moreover, the adhesive technique enables small particles to be embedded in the adhesive and thus do not interfere further with the bonding process, thereby ensuring that the cell remains leaktight. The requirements placed on the cleanness of the process surroundings are thereby correspondingly less stringent.

The method according to the invention provides, in particular, that a disc-shaped glass element with a thickness of at most 700 micrometers, preferably at most 500 micrometers, is structured in such a way that it has at least one opening that connects the two opposite-lying, parallel side faces of the glass element, and to join each of the side faces of the glass element with a glass part, so that the opening is sealed by the two glass parts, and a microfluidic cell is formed, having a cavity that is enclosed between the other glass parts and is suitable for the conveyance of liquids, wherein the attachment of the glass element to at least one of the two glass parts is produced by an applied adhesive, wherein, during application of the adhesive, at least one opening in the glass element is left free of adhesive. The adhesive is preferably applied onto the side faces of the glass element. However, a structured application is also possible on corresponding surfaces of the glass parts.

Preferably, even still thinner glasses are used for the middle glass element, namely, with a thickness of at most 300 micrometers—for example, 210 micrometers or less. It is even possible to structure glasses of 100 micrometers or thinner, such as, for instance, at most 70 μm, and to utilize them as a glass element for the microfluidic cell. For especially small structures, it is also possible to structure the thinnest glasses of at most 70 μm, preferably at most 50 μm, or even only at most 30 μm, with openings. This method affords a microfluidic cell that comprises a disc-shaped glass element with a thickness of at most 700 micrometers, preferably at most 300 micrometers, which is structured in such a way that it has at least one opening, which connects the two opposite-lying parallel side faces of the glass element, wherein each of the side faces of the glass element is attached to a glass part, so that the opening is sealed by the two glass parts and a cavity is present, which is enclosed between the two glass parts and is suitable for the conveyance of fluids, wherein the glass element is attached to at least one of the two glass parts through an adhesive layer, wherein the adhesive layer is left out of at least one opening in the glass element.

In particular, in an enhancement of the invention, it is provided that the glass element is structured with an opening having an elongated shape, so that, when the opening is sealed by the glass parts, a cavity is created in the form of a fluid-carrying channel. For the above-described microfluidic cell, it is possible to utilize various structuring methods in order to produce the one opening or the plurality of openings in the glass element. A preferred structuring using a laser-assisted etching process is described further below, but it is entirely possible also to utilize other suitable structuring methods. A challenge consists in furnishing with adhesive the surfaces of the ultrathin structured glass (for example, with a thickness of 100 μm) that are to undergo adhesive bonding, which have crosspieces with a width as small as several hundred micrometers and channel structures with a length of several centimeters (1-20 cm), without any damage to them (for example, hairline cracks, glass breakage), in such a way that exclusively or mainly the bonding faces, but not the side faces forming the channel walls, are coated. This is advantageous, because excess adhesive could interfere with the reactions in the microfluidic cell. For this purpose, in an enhancement of the invention, it is provided that the application of the adhesive is performed by means of a structured application method, in particular a printing method, in which the adhesive is applied selectively onto the side face so as to leave out a region extending over the opening in the glass element. Suitable as structured printing methods are, in particular, pad printing, screen printing, stencil printing, inkjet printing or other computer-controlled valve jet methods, roll coating or roll-to-roll coating by means of a structured roll, dispensing, or stamp transfer.

Especially preferred is adhesively bonding the two glass parts to the glass element. However, the adhesive bonding of the glass element to one of the two glass parts can also be combined with another method of attachment for the other glass part. For example, one of the glass parts could also be welded on, anodically bonded, directly bonded, or else soldered with a glass solder to the glass element.

In general, silicones, epoxy resins, acrylates, or polyurethanes are suitable as adhesives or the constituents thereof. In accordance with another advantageous embodiment, a pressure-sensitive contact adhesive is used.

In general, it is also preferred when an adhesive with little fluorescence, in particular an adhesive without any fluorescence, is used. This diminishes background signals during fluorescence measurements on the microfluidic cell.

In order to prevent any entry of adhesive into the opening, it is especially advantageous when the printing of the adhesive is produced in such a way that the region left free is larger than the opening, so that the edge of the applied adhesive layer is spaced apart from the edge of the opening and, in particular, is set back.

In general, and regardless of how the adhesive application occurs, it is preferred in any case that the adhesive is applied in such a way that the edge of the opening remains free of adhesive.

In accordance with another embodiment, a plastic film pre-structured with the recess is applied. The plastic film then forms the adhesive layer. In particular, such a plastic film can be furnished with a pressure-sensitive adhesive or a so-called PSA (pressure sensitive adhesive) in order to adhesively bond the glass element to the respective glass part 5. In accordance with another embodiment, a pressure-sensitive adhesive on a strip material in the form of a detachable support is used. Such a support is also referred to as a “liner.” Accordingly, the liner with the pressure-sensitive adhesive can be applied onto the glass element or glass part and then peeled off, so that only the pressure-sensitive adhesive remains on the glass element or glass part. Consequently, the liner represents a strip material, typically a film, that exhibits little adhesion to the pressure-sensitive adhesive. The use of a liner is advantageous in order to reduce the layer thickness of the adhesive bonding when a pressure-sensitive adhesive is utilized.

Furthermore, it is favorable when the adhesive layer thickness is at least on the order of magnitude of the variation in thickness of the glass. On the other hand, however, variations in the adhesive thickness should be limited to a maximum of 20%, preferably a maximum of 10%, so that the leaktightness can be ensured.

Moreover, it is favorable to design the printing method in such a way that flaws in the adhesive layer are limited to a size that is less than the minimum crosspiece width of the respective structure, that is, for example, less than the minimum separating distance of adjacent channels.

The method is suitable especially in conjunction with a laser-based structuring method for the production of the fluid-carrying structures of the cell. Provided for this purpose, in accordance with a further aspect of the invention, is a method for producing microfluidic cells in which a disc-shaped glass element with a thickness of at most 300 micrometers is structured in such a way that it has at least one opening, which connects the two opposite-lying, parallel side faces of the glass element, wherein each of the side faces of the glass element is attached to a glass part, so that the preferably elongated opening through the two glass parts is sealed and a microfluidic cell having a cavity, which is enclosed between the two glass parts and is suitable for the conveyance of fluids, is formed, wherein the opening in the glass element is produced in that the laser beam of an ultrashort-pulse laser is directed onto one of the side faces of the glass element and, by use of focusing optics, is concentrated to an elongated focus in the glass element, wherein, as a result of the irradiated energy of the laser beam, filament-shaped damage is created in the volume of the glass element, the longitudinal direction of which extends transversely to the side face, in particular, perpendicularly to the side face, and, for creation of filament-shaped damage, the ultrashort-pulse laser radiates one pulse or a pulse packet containing at least two laser pulses following one another, and wherein, after the insertion of the filament-shaped damage, the glass element is exposed to an etching medium, which removes glass of the glass element at a removal rate that is preferably less than 8 μm per hour and widens the filament-shaped damage to form a channel. Typically, the etching method inserts rounded, dome-tshaped depressions into the wall of the channel. The attachment of the disc-shaped glass element to the two glass parts can be produced, as described above, by adhesive bonding, in particular by means of a structured application of adhesive. Also conceivable in general, however, are other methods of attachment, such as, for instance, anodic bonding, direct bonding, or laser welding.

By use of the above-described method, it is also possible to produce larger openings, in particular also elongated openings, for the production of channels. For this purpose, in an enhancement of the invention, it is provided that a large number of filament-shaped damage insertions are created side by side and the diameter of the channels is sufficiently enlarged by the etching until the glass between the channels is removed and the channels combine.

### BRIEF DESCRIPTION OF THE DRAWINGS

The invention will be explained below in detail and with reference to the appended drawings.

FIG. 1 is an exploded illustration of a microfluidic cell.

FIG. 2 is a sectional illustration of the elements of a microfluidic cell.

FIG. 3 shows the elements in accordance with FIG. 2 in assembled form.

FIG. 4 shows an arrangement for application of the adhesive.

FIG. 5 shows an apparatus for laser processing of a glass element as preparation for insertion of an opening.

FIG. 6 shows a glass element with filament-shaped damage insertions.

FIG. 7 shows the glass element with channels inserted along the filament-shaped damage.

FIG. 8 represents the glass element 3 from FIG. 7 after release of a part.

FIG. 9 shows a variant of the glass element from FIG. 7.

FIG. 10 and FIG. 11 are electron micrographs of an edge of a glass element in different magnifications.

FIG. 12 and FIG. 13 show electron micrographs of channels in another glass, which were inserted using various laser parameters.

FIG. 14 and FIG. 15 are electron micrographs of an edge of a glass element in different magnifications.

FIG. 16 shows a part of a glass element having a crosspiece between two openings.

FIG. 17 shows a glass element having structures held by crosspieces.

FIG. 18 represents a microfluidic cell having a multilayer structure.

FIG. 19 shows a variant of the invention with a recess that connects two cavities.

FIG. 20 shows a further variant having a recess in the glass element.

FIG. 21 represents a glass element with filament-shaped damage.

FIG. 22 shows a glass element with a pattern of filament-shaped damage in top view.

FIG. 23 shows an arrangement for the insertion of filament-shaped damage in a glass element.

### DETAILED DESCRIPTION

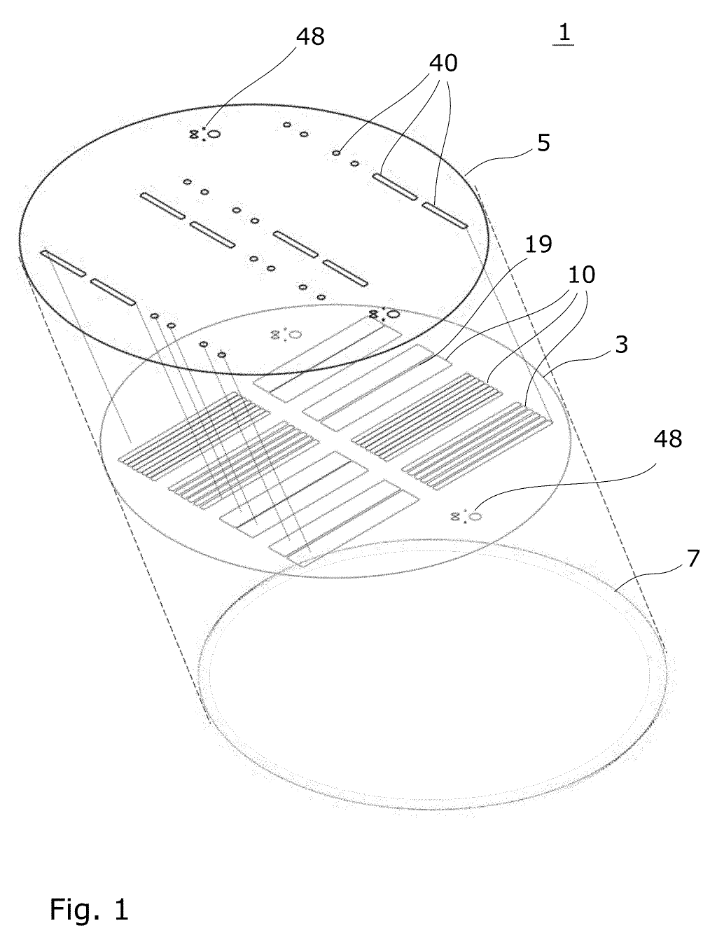

FIG. 1 shows an exploded drawing of a microfluidic cell 1 such as can be produced by means of the invention. The microfluidic cell 1 comprises a disc-shaped glass element 3, the side faces of which are attached to two glass parts 5, 7, which typically are likewise disc-shaped. Without any limitation to the illustrated example, it is provided in accordance with one embodiment of the invention that the glass parts 5, 7 form the bottom and the cover of the microfluidic cell 1. For the highlighting of the structuring of the parts in the exploded drawing, the disc-shaped glass element 3 and the glass parts 5, 7 are illustrated separately from each other.

As can be seen in the illustration, the disc-shaped glass element 3 has a plurality of adjacently lying elongated openings 10. The latter are separated from one another in part by narrow webs or crosspieces 19, respectively. If the glass parts 5, 7 are attached to the disc-shaped glass element 3, then the elongated openings 10 are sealed by the two glass parts 5, 7, and cavities are formed that particularly form elongated channels corresponding to the shape of the openings 10 running in the direction along the side faces of the glass element 3.

Even very thin crosspieces 19 can be printed with the adhesive. In one embodiment of the invention, it is provided that a glass element 3 having at least two adjacently extending openings 10 are provided, which are separated from each other by a crosspiece 19 that has a minimum width of at most 400 μm, wherein the crosspiece of the glass element 3 is attached to the glass part 5 or 7 by using an adhesive. In the illustrated example, a group of openings 10 has been produced, which are separated by crosspieces 19 with a crosspiece width of 300 μm. In order to further ensure a tight attachment and in order to prevent or at least to reduce any entry of adhesive onto the wall of the cavity formed from the opening, a minimum width of the crosspiece of at least 50 μm is preferred.

In order to attach the glass parts 5, 7 to the disc-shaped glass element 3, it is then provided that adhesive is applied onto the surfaces to be attached. Preferably, the application of adhesive is produced, at least for the attachment to one of the glass parts 5, 7, on the disc-shaped glass element 3. However, the application of adhesive can also be made on a corresponding surface of the glass part 5 or 7 that is to be attached.

As can be further seen on the basis of FIG. 1, at least one of the glass parts 5, 7 has an opening 40. Typically, as in the illustrated example and depending on the design of the microfluidic cell 1, a plurality of such openings 40 are present. The openings 40 serve as filling openings for fluids and therefore correspond to at least one opening 10 in the glass element 3 in each case.

In an enhancement of the invention, without any limitation to the illustrated example, it is therefore provided that, in at least one of the glass parts, an opening 40 is present or is inserted into the glass part 5, 7, wherein the glass part 5, 7 is combined with the glass element in such a way that the opening 40 produces a connection to the opening 10 in the glass element 3 and hence produces a fluid-carrying connection in the cavity that is produced in the glass element 3 from the opening 10 when it is sealed to the two glass parts 5, 7. For example, the opening 10 in elongated shape can form a cavity 9 in the form of a thin channel, along which a fluid that is provided at the opening 40 in the glass part 5, 7 is conveyed. In one exemplary embodiment, as the glass element 3, an interposer with a thickness of 80 micrometers was adhesively bonded to a glass element 5 with a thickness of 0.7 millimeter as a cover and to a glass element 7 as a bottom with a thickness of 0.3 millimeter.

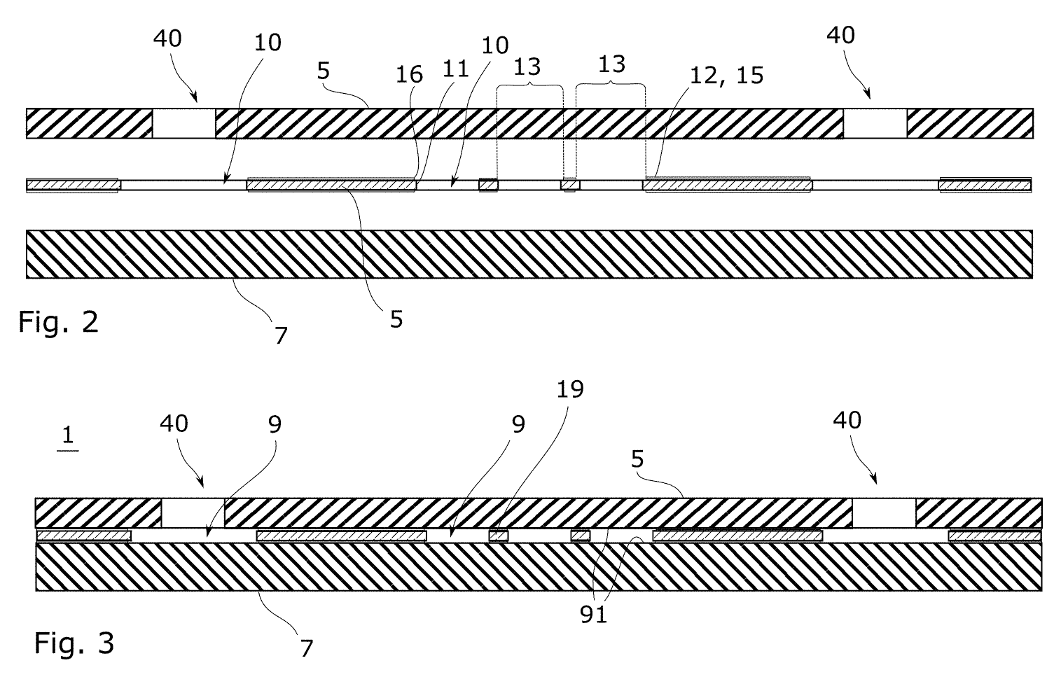

FIG. 2 shows, in sectional illustration, the parts of the microfluidic cell, namely, the glass element 3 and the glass parts 5, 7, which form the cover and the bottom of the cell, prior to being joined together. FIG. 3 shows the elements in accordance with FIG. 2 in assembled form, that is, the microfluidic cell 1 that is formed with the glass parts 5, 7 and the glass element 3.

The attachment of the glass element 3 to the two glass parts 5, 7 is produced by an applied adhesive 12. During application of the adhesive 12, the openings 10 in the glass element 3 are left free. It is thereby prevented that the adhesive reaches the edges 11 of the openings 10 and, as a result, after completed fabrication of the cell, is present in the cavities 9 formed from the openings. The adhesive 12 is applied as a thin adhesive layer 15. In the illustrated example, the application is produced on both sides of the glass element 3. However, it is also conceivable to apply the adhesive for one or both joints onto a glass part 5, 7. In any case, however, the adhesive is applied in such a way that the edge of the opening 10 that later forms the side wall of a cavity produced using the opening 10 remains free of adhesive.

The adhesive layer 15 can also be applied as an adhering film—for example, as a film furnished with a pressure-sensitive adhesive.

In general, it may be desirable to prefabricate the glass element 3 with the adhesive layers 15 and to join the glass parts 5, 7 thereto only at a later point in time. This is the case, for example, when one or both of the glass parts 5, 7 is or are furnished with biomarkers or, in general, biofunctional molecules, which, after the attachment thereof, can then adhere to the wall of the cavity 9 and react with constituents of an added fluid. Thus created, in general, is a microfluidic cell 1 for which the glass element 3 is attached to at least one of the glass parts 5, 7 by an adhesive layer 15, whereby the adhesive layer 15 has a region 13 that remains free of adhesive around the at least one opening 10, so that the part of the wall of the cavity 9 formed by the glass part 5, 7 is left free of the adhesive layer 15, and whereby at least this part of the wall of the cavity 9 is furnished with adhering biofunctional molecules, in particular biomarkers. If the biofunctional molecules are applied over the entire surface, then they are also situated in the adhesively bonded region, where, of course, however, they cannot come into contact with the fluid that is to be treated.

In order to be able to perform such a later adhesive bonding with individually furnished glass parts 5, 7, for example, the invention also relates to an intermediate product for producing a microfluidic cell 1 having a disc-shaped glass element 3 with a thickness of at most 700 micrometers, which is structured in such a way that it has at least one opening 10, which connects the two opposite-lying parallel side faces 30, 31 of the glass element 3, wherein each of the two side faces 30, 31 is furnished with an adhesive layer 15 in order to attach the side faces 30, 31 to the glass parts 5, 7, so that the opening 10 is sealed, and a microfluidic cell 1 having a cavity 9 that is suitable for the conveyance of fluids is formed, wherein the adhesive layer 15 leaves free the at least one opening 10 in the glass element 3.

As can be seen on the basis of FIG. 2, the printing of the adhesive 12 can be produced in such a way that the regions 13 that are left free of adhesive are larger than the corresponding openings 10, so that the edge 16 of the applied adhesive layer 15 is spaced apart from the edge 11 of the respective opening 10 and, in particular, is set back. It is thereby prevented that, under pressure, the adhesive spreads laterally so far that it enters the opening 10.

In general, thin adhesive layers 15 are preferred. In accordance with one embodiment of the invention, it is preferred that the adhesive 12 is applied with a thickness of at most 50 μm, preferably at most 20 μm. As mentioned above, however, it is favorable when the adhesive layer thickness is at least of the magnitude of the variation in thickness of the glass. In general, it is preferred that the thickness of the applied adhesive layer is at least 2 μm.

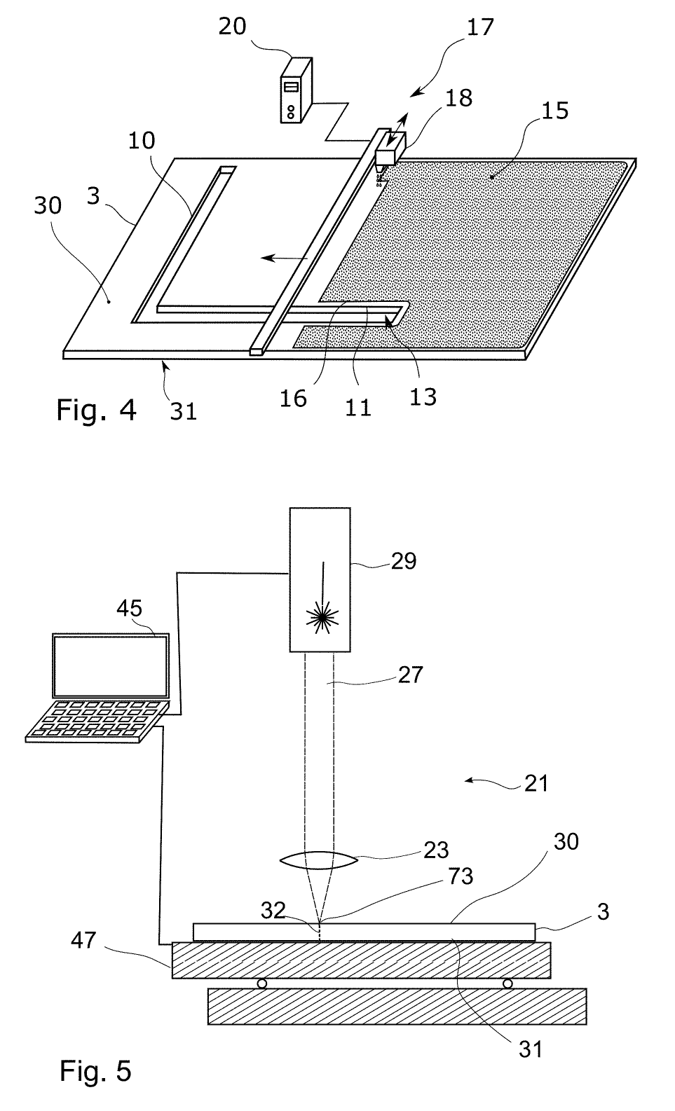

FIG. 4 shows an arrangement for applying the adhesive layer 15 onto the glass element 3 or onto one of the glass parts 5, 7. The application of the adhesive 12 is produced by means of a structured printing method, in which the adhesive is applied selectively—leaving out a region 13 that extends over the opening 10 in the glass element 3—onto the respective side face 30, 31 of the glass element. For this purpose, in accordance with one embodiment of the invention, a printing apparatus 17, which has a printing head 18 actuated by a computer 20, is used. The printing head can be, in particular, an inkjet printing head, which is moved over the glass element 3 and dispenses the adhesive drop by drop. The computer controls the printing head in such a way that the region 13, in which the elongated opening 10 lies, is left free. For example, the printing head can be moved along a meandering path over the glass element 3, whereby the printing head is moved forwards and backwards at a traverse and the traverse, or alternatively the glass element 3, is shifted line by line.

As illustrated, the region 13 can be kept larger than the opening 10, so that the edge of the left-free region is spaced apart somewhat from the edge 11 of the opening 10. In addition to the embodiment with an ink-jet printing head, it is also possible for other methods to be used. Other printing methods are pad printing, screen printing, stencil printing, roll coating or roll-to-roll coating, dispensing, and stamp transfer. Suitable especially for larger unit numbers are printing methods such as pad printing and screen printing. In an exemplary embodiment, for the production of a structure of a microfluidic cell such as that shown in FIG. 1 by means of screen printing, an acrylate adhesive with a viscosity of 9600 mPa·s is applied on both sides of the glass element 3. By use of the positioning markers 48, it is possible to align not only the glass element 3 with respect to the glass part 5, but also to align the screen-printing mask to the structure of the microfluidic cell.

The viscosity of the adhesive can generally also be adjusted to the printing method. Thus, for pad printing, lower viscosities—for example, in the range around 300 mPa·s—are preferred. In the inkjet method, illustrated by way of example in FIG. 4, even lower viscosities—preferably less than 50 mPa·s—are preferred.

A preferred embodiment of the invention provides the application of a photocurable, preferably UV-curable, adhesive 12. The adhesive 12 can then be irradiated with light, preferably UV light, through one of the glass parts 5, 7, so that the adhesive is hardened and the glass part, or, in the case of two-sided application, both glass parts 5, 7 are firmly adhesively bonded to the glass element 3. Suitable adhesives, which can also be UV-curable, are silicone-containing adhesives, epoxy resins, and acrylates.

Described below is a preferred embodiment of the structuring of the glass element 3 in order to introduce one elongated opening or a plurality of elongated openings 10. The opening 10 in the glass element 3 is produced in that the laser beam 27 of an ultrashort-pulse laser 29 is directed onto one of the side faces 30, 31 of the glass element 3 and, by using a focusing optics 23, is concentrated to an elongated focus in the glass element 3, whereby, through the irradiated energy of the laser beam 27, filament-shaped damage 32 is produced in the volume of the glass element 3, the longitudinal direction of which extends transversely to the side faces 30, 31, in particular perpendicularly to the side faces 30, 31, and, for the creation of filament-shaped damage by the ultrashort-pulse laser 29, one pulse or a pulse packet containing at least two laser pulses following one another is or are radiated and whereby, after inserting the filament-shaped damage 32; the glass element 3 is exposed to an etching medium, which removes the glass of the glass element 3 at a removal rate of preferably less than 8 μm per hour; and widens the filament-shaped damage 32 to form a channel 35; and introduces rounded, dome-shaped depressions into the walls of the channel.

In FIG. 5, an exemplary embodiment for a laser processing apparatus 21 is shown, with which filament-shaped damage insertions 32 can be made in a glass element 3 in order to subsequently, in an etching process, insert channels at the sites of the filament-shaped damage 32. The apparatus 21 comprises an ultrashort-pulse laser 30 having an upstream focusing optics 23 and a positioning device 47. By use of the positioning device 47, the point of impingement 73 of the laser beam 27 of the ultrashort-pulse laser 30 on the side face 2 of a plate-shaped glass element 3 that is to be processed can be laterally positioned. In the illustrated example, the positioning device 47 comprises an x-y stage, on which the glass element 3 rests on a side face 31. Alternatively or additionally, however, it is also possible to construct the optics to be movable in order to move the laser beam 27, so that the point of impingement 32 of the laser beam 27 can be moved while the glass element 3 is held in place.

The focusing optics 23 then focus the laser beam 27 to form an elongated focus in the direction of the beam, that is, accordingly transversely and, in particular, perpendicularly to the irradiated side face 30. Such a focus can be produced, for example, with a cone-shaped lens (a so-called axicon) or with a lens having a large spherical aberration. The control of the positioning device 47 and of the ultrashort-pulse laser 30 is preferably performed by means of a computing device 45 set up to run a program. In this way, it is possible to produce predefined patterns of filament-shaped damage 32 distributed laterally along the side face 2; this is accomplished, in particular, by reading in positional data, preferably from a file or via a network.

In accordance with one exemplary embodiment, the following parameters can be used for the laser beam.

The wavelength of the laser beam is 1064 nm, which is typical for a YAG laser. A laser beam with a raw beam diameter of 12 mm is produced, which is then focused using an optics in the form of a biconvex lens with a focal length of 16 mm. The pulse length of the ultrashort-pulse laser is less than 20 ps, preferably about 10 ps. The pulses are delivered in bursts of 2 or more pulses, preferably 4 or more pulses. The burst frequency is 12-48 ns, preferably about 20 ns, the pulse energy is at least 200 microjoules, and the burst energy is correspondingly at least 400 microjoules.

Subsequently, after one filament-shaped damage insertion, or, in particular, a plurality of filament-shaped damage insertions 32, the glass element 3 is removed and placed in an etching bath, where, in a slow etching process, glass is removed along the filament-shaped damage insertions 32, so that, at the site of such a damage insertion 32, a channel is inserted into the glass element 3 in each case.

Without any limitation to special exemplary embodiments, generally a basic etching bath, with a pH value of >12, such as, for example, a KOH solution containing >4 mol/L, preferably >5 mol/L, especially preferred >6 mol/L, but <30 mol/L is preferred. The etching is performed in accordance with one embodiment of the invention, regardless of the etching medium used, at a temperature of the etching bath of >70° C., preferably >80° C., and especially preferably >90° C. The etching using a basic etching bath leads to the structure with dome-shaped depressions. However, it is also possible to perform etching using an acidic etching medium.

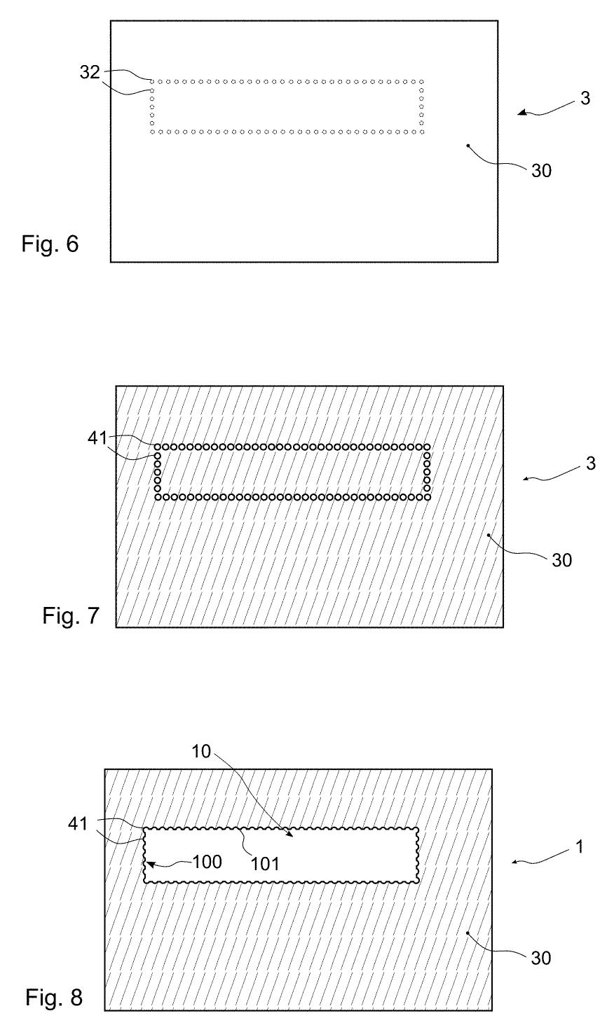

FIG. 6 shows, in a top view of a side face 30, a glass element 3 with a plurality of filament-shaped damage insertions 32, which are arranged in a specific pattern that can be inscribed in the glass element 3 by the above-described computer-controlled actuation of the positioning device 47 and of the ultrashort-pulse laser 29. In particular, the filament-shaped damage insertions 32 in this case are made in the glass element 3, by way of example, along a predetermined path in the shape of a closed rectangular line. The corners of the line can also be slightly rounded. It is self-evident to the person skilled in the art that, by use of the method, not only rectangular, but also paths of any desired shape can be traveled. The arrangement of the filament-shaped lines corresponds to the outline of an elongated opening that is to be inserted into the glass element.

FIG. 7 shows the glass element 3 after a subsequent etching step. Instead of the filament-shaped damage insertions 32, channels 41 are now present, which are arranged and aligned next to one another along the predetermined path. The glass element 3 is illustrated cross-hatched in order to distinguish graphically the element of openings, as they are also represented by the channels 41.

The channels 41, which are inserted next to one another along the path traveled by the laser, can then serve as desired breakage sites in order to release a part of the glass element 3 or to separate the glass element 3 along this path in order to obtain an opening 10.

FIG. 8 shows the glass element 3 after the separation along the path. Because the channels 41 were arranged along closed lines of separation, which here, by way of example, are rectangular, the separation results in the release of an inner part and in the creation of an opening 10 in the glass element 3.

Quite generally, without any limitation to the special exemplary embodiment, a separation along one channel or a plurality of channels 41 then results in the creation of a plate-shaped glass element 3 having a channel 41, which is open on the side and forms a part of the edge 100 of the opening 10.

Furthermore, glass material was still present between the channels 41, as shown in FIG. 7. In accordance therewith, the inner part and the surrounding glass element 3 were still attached to each other after the etching. The final separation can then be produced, for example, by breaking. On account of the perforations created by the adjacently arranged channels 41, the glass element 3 breaks along the path of the aligned channels 41. In general, without any limitation to the illustrated example, an edge 100 is produced in this way, for which, as illustrated in FIG. 8, flat edge sections extend between the channels 41. In this case, the flat edge sections 11 are formed during breakage of the glass between the channels 41.

In order to release an inner part and/or to produce an opening 10 in a glass element 3, a variant of the above-described method is especially suitable. This embodiment of the invention is based on the fact that, as a result of the etching, the diameter of the channels 41 is enlarged to such an extent that the glass between the channels 41 is removed and the channels 41 combine.

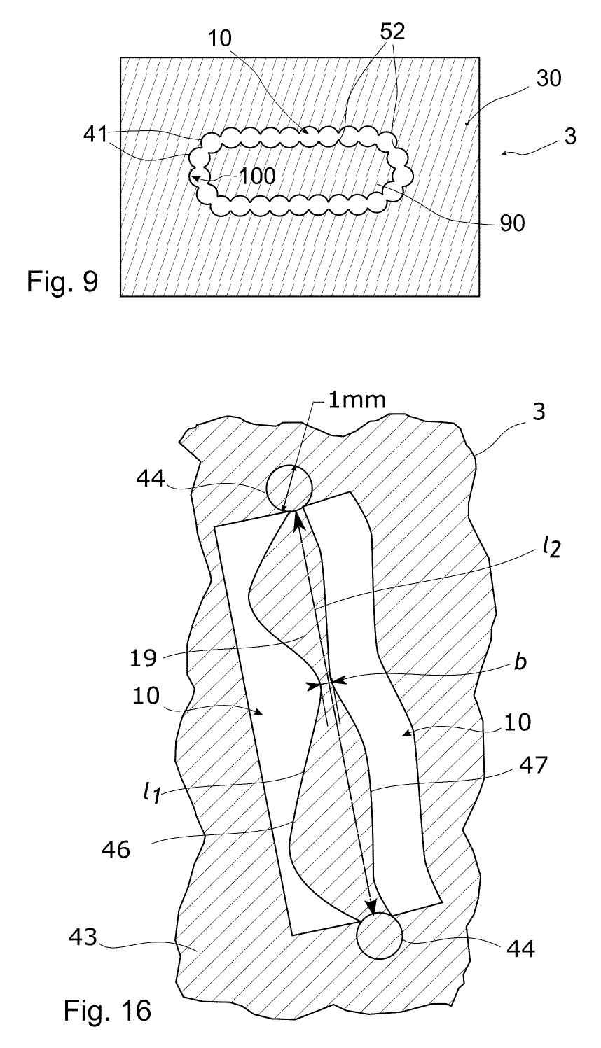

FIG. 9 shows a glass element 3 in which the channels 41 have combined laterally during etching. As in the case of the example of FIG. 8, the channels 41 are aligned next to one another along a closed path. In accordance therewith, the release results, in turn, in an opening 10 and produces a complementary inner part. In the illustrated example, although the inner part 90 has already been separated, it is still arranged in the opening 10.

FIG. 6 to FIG. 9 are examples of an embodiment of the invention, in accordance with which an edge 10 of the glass element 3 that has a plurality of parallel adjacently extending, laterally open channels 41 is created.

Furthermore, all of these examples are based on an embodiment of the method according to the invention, in which the point of impingement 73 of the laser beam 27 on the glass element 3 is guided along a predetermined path, and a plurality of filament-shaped damage insertions 32 that lie adjacent to one another on the path, and subsequently, as a result of the etching, a plurality of adjacently lying channels 41 are inserted into the glass element 3, and the glass element 3 is then separated along the path, so that an edge 100 with laterally open channels 41 is formed.

The channels 41 have, in general, a tube-shaped, cylindrical basic shape or are tube-shaped with cylindrically formed walls. It is thereby possible for a slight tapering of the opening to be present at the side face toward the middle of the glass element 3. During the combination of the generally cylindrically formed channels 41 in the course of the widening during the etching process, ridges can form at the abutting sites. In general, without any limitation to the example of FIG. 9, it is provided in accordance with one embodiment of the invention that the channels 41 border one another, so that, between the channels 41, ridges 52 that extend parallel to the longitudinal direction of the channels 41 are formed.

Accordingly, these ridges or ribs extend parallel to the longitudinal direction of the channels and, in the illustration of FIG. 8, can therefore be seen only as serrated or tooth-shaped elements at the site of the transition region of adjacent channels 41.

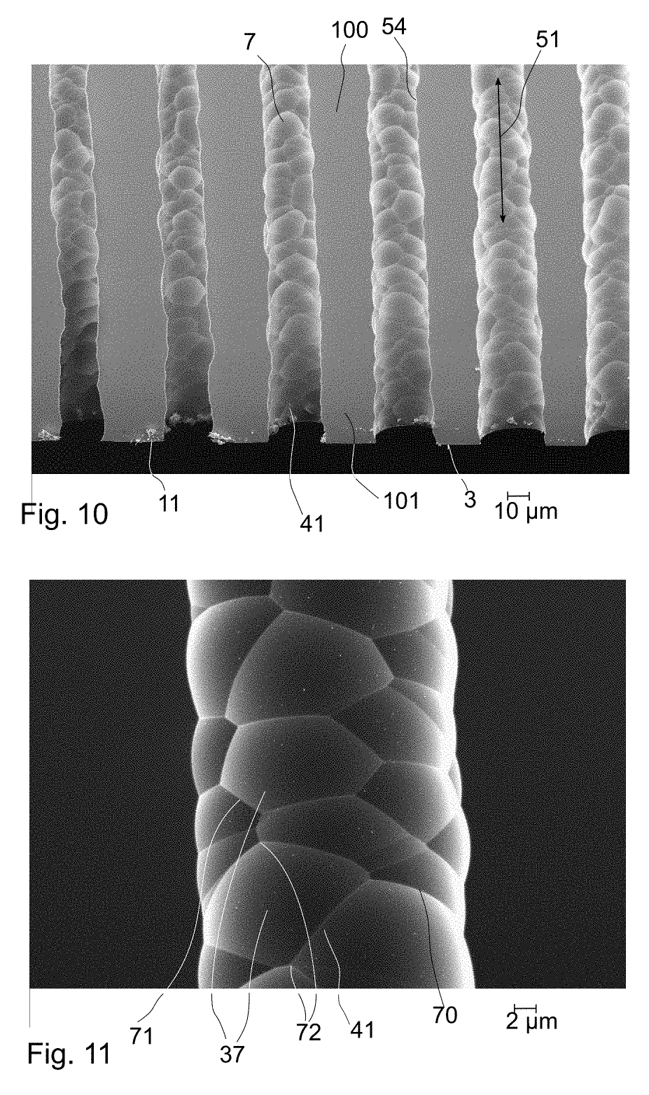

FIG. 10 and FIG. 11 show electron micrographs of the edge 100 of a glass element 3 that has been processed in accordance with the invention. In this case, FIG. 11 was photographed at a larger magnification. As in the case of the examples of FIG. 8 and FIG. 9, the edge 100 has a plurality of parallel, adjacently extending, laterally open channels 41. In the illustration of FIG. 10 in a top view of the edge 100, it can now be seen that the longitudinal direction 51 extends transversely, and, in particular, perpendicularly to the side faces 2, 3. In the section shown in FIG. 10, however, only the transition of the edge 100 at the edge 11 of an opening to one of the side faces, which is identified here as the side face 30, can be seen. Corresponding to the example of FIG. 3, the edge 10 has, besides the laterally open channels 41, also flat edge sections 101. The edge 10 was consequently produced by breaking at the separating line weakened by the channels 41.

In this example, the separating distance of the channels 41 is relatively large, being about 50 μm. The separating distance can also be chosen to be smaller, in particular in the case when the channels 41 transition directly into one another without any flat edge sections 101. In general, the separating distance of the channels (also referred to as the “pitch”) is preferably in the range of 3 to 70 micrometers. This separating distance is measured here from the middle of one channel to the middle of the adjacent channel. The transverse dimension or the diameter of the channels 41 is preferably less than 100 micrometers. Preferably, the diameter lies in a range that is similar to the separating distance of the channels 41. Without any limitation to the examples described here, a diameter that lies in the range of 3 micrometers to 50 micrometers is preferred. In the example of FIG. 10 and FIG. 11, the diameter is about 30 micrometers.

As can be seen on the basis of FIG. 10 and FIG. 11, the etching also results, in particular, in the formation of dome-shaped depressions 37.

Accordingly, without any limitation to the examples illustrated, the invention generally also relates to a microfluidic cell 1 having a disc-shaped glass element 3 with a thickness of at most 300 micrometers, which has at least one elongated opening 10 that connects the two opposite-lying parallel side faces 30, 31 of the glass element 3, wherein each of the side faces 30, 31 of the glass element 3 is attached to a glass part 5, 7, so that the elongated opening 10 through the two glass parts 5, 7 is sealed and an enclosed cavity 9 is formed between the two glass parts 5, 7 and is suitable for the conveyance of fluids, wherein the edge 100 of the opening 10 or, accordingly, only the part of the wall of the cavity that is formed by the edge 100 of the opening 10 has dome-shaped depressions 37.

In the case of microfluidic cells, this structure of the cavity 9 has the special advantage that the dome-shaped depressions at the side walls improve the wettability for fluids. This ensures an improved ability to fill the cell.

This embodiment is independent of the way in which the glass element 3 is attached to the glass parts 5, 7. The above-described adhesive bonding is preferred, but other methods of attachment, such as, for instance, anodic bonding or direct bonding as well as also welding or soldering using glass solder, are possible. In accordance with an enhancement of the invention, therefore, without any limitation to special exemplary embodiments or to the figures, the glass element 3 is attached to at least one of the glass parts 5, 7 through an adhesive bond or an anodic bond or a direct bond or a weld or a glass solder. In the case of adhesive bonding, the above-explained structured coating with an adhesive layer 15 is preferred.

In accordance herewith, in an enhancement of the invention, it is provided that the glass element 3 is attached to at least one of the glass parts 5, 7 through an adhesive layer 15, wherein the adhesive layer 15 has a region 13 that is left free of adhesive around the at least one opening 10, so that the part 91 of the wall of the cavity 9 formed by the glass part 5, 7 is left free of the adhesive layer. In particular, therefore, this part 91 of the wall can thereby be formed by the surface material of the glass part 5, 7. The regions 91 are marked in FIG. 3. In particular, in a preferred embodiment of the invention, it is also provided that the edge 100 of the opening 10 is free of adhesive in the glass element.

The depth of the dome-shaped depressions 37 is typically, that is, on average, less than 5 μm; for transverse measurements, on average, 5-20 μm. In accordance with an enhancement of the invention, the etching is thus carried out in such a way that at least one of the aforementioned features of the dome-shaped depressions is obtained.

It can be seen that, not only owing to the depressions 37, but especially owing to the channels 41, the surface of the edge 100 is larger than the surface of a flat edge. This fine structure, too, improves the wettability of the cavity 9.

In accordance with one aspect of the invention, therefore, a microfluidic cell 1 having a glass element 3 with two opposite-lying side faces 30, 31 and an elongated opening 10, which is delimited by an edge 100, is provided, wherein, at the side faces 30, 31, the glass parts 5, 7 are fastened, so that the opening 10 forms a cavity 9 between the glass parts 5, 7, wherein the edge 100 of the opening has a plurality of parallel, adjacently extending, laterally open channels 41 with rounded walls 54 and with a transverse dimension of less than 200 μm, the longitudinal direction 51 of which extends transversely, preferably perpendicularly, to the side faces 30, 31 of the glass element 3, and these channels preferably also end at the side faces 30, 31 or open into them. As such, this embodiment is also independent of the kind of attachment of the glass element 3 to the glass parts 5, 7 and, furthermore, is also independent of whether dome-shaped depressions are created by the etching. Preferably present, however, are both the depressions 37 and an adhesive layer 15 for attachment to the glass part or glass parts 5, 7.

If the channels 41 directly bordered one another and had an exactly semicircular cross section, then the length of the edge line parallel to the side faces 30, 31 would be larger than the edge line of a smooth edge by a factor of π/2. The enlargements of the surface area that can be achieved using the method according to the invention are, in general, somewhat smaller and typically lie in the range of 10 to 40 percent. Correspondingly, in an enhancement of the invention, it is provided that the surface of the edge 100, due to the channels 41, is enlarged by a factor of 1.1 to 1.4 in comparison to a smooth edge surface area without channels 41.

This enlargement of the surface affords, as a further side effect, an edge that is relatively resistant to breakage under bending loads. This is surprising insofar as, normally, the probability of breakage is scaled to the surface area. The structures that protrude with respect to the rounded channel likely lead to the fact that defects are not able to propagate at these protruding structures (ridges or flat edge sections). As a result of the structuring of the edge 11, the propagation of cracks is thus suppressed. The microfluidic cell 1 is thus also more stable mechanically.

On the basis of FIG. 10 and FIG. 11, the fine structure of the channels 41 can clearly be seen in the form of dome-shaped or rounded, cap-shaped depressions 37. As a result of the preferred slow etching process, the dome-shaped depressions 37 border one another and the concave roundings of the depressions 7 that abut one another create ridges 70.

Furthermore, it can be seen that, in a top view of the depressions 37, the ridges 70 form polygonal boundary lines 71 of the depressions 37. In this case, the mean number of corners 72 of the boundary lines 71 of the depressions 7 is preferably also less than eight, preferably less than seven. The latter feature results when the regions occupied by most of the dome-shaped depressions are convex in the mathematical sense.

In one embodiment of the invention, therefore, a microfluidic cell 1 is provided, for which the dome-shaped depressions 37 in the edge 100 of the opening 10 border one another and the concave roundings of the depressions 37 that are in abutting contact with one another create ridges 70. In an enhancement of this embodiment, it is further provided that, in a top view of the depressions 37, the ridges 70 form polygonal boundary lines 71 of the depressions 37.

The ridges 70 of the channel 41 shown in FIG. 7 are very narrow; there are no visible regions in which the concave archings of the depressions 37 transition into one another via a convexly arched region at the ridge 70. Therefore, the structure of the channels 41 can also be described in accordance with an enhancement of the invention in such a way that the surface fraction of convexly formed regions in a channel 41 is less than 5% and preferably less than 2%.

The glass element 3 in the example of FIG. 10 and FIG. 11 is a silicate glass with a low alkali content, in particular a borosilicate glass with a thermal expansion coefficient of 3.3*10⁻⁶ K⁻¹. As borosilicate glass, a glass with the following composition is preferred:

| Composition | (wt %) |
|---|---|
| SiO₂ | 63-83 |
| Al₂O₃ | 0-7 |
| B₂O₃ | 5-18 |
| Li₂O + Na₂O + K₂O | 4-14 |
| MgO + CaO + SrO + BaO + ZnO | 0-10 |
| TiO₂ + ZrO₂ | 0-3 |
| P₂O₅ | 0-2 |

This glass can also be used for the glass parts 5, 7.

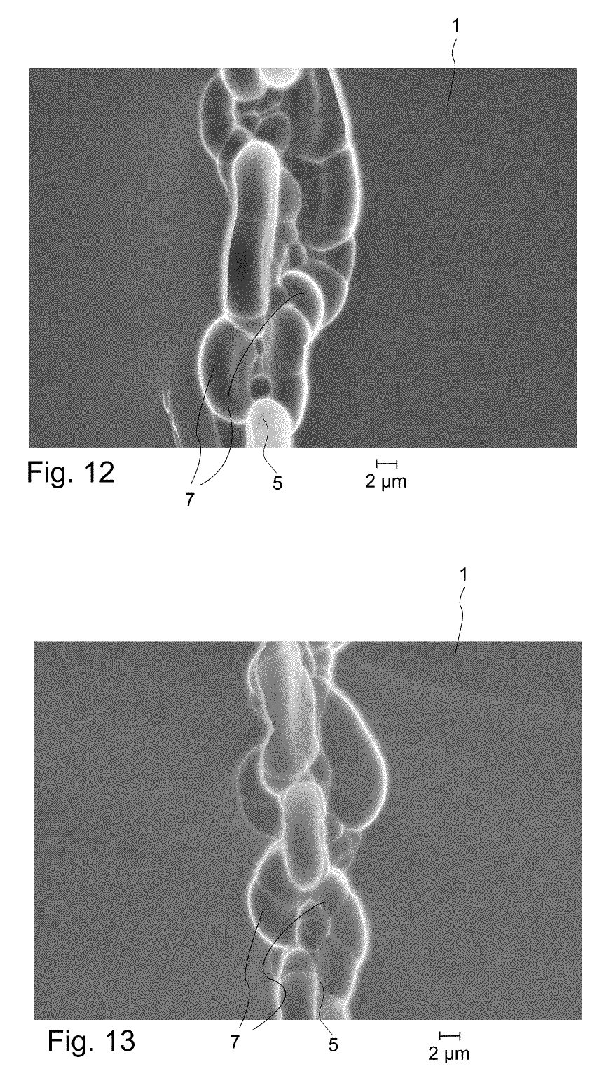

FIG. 12 and FIG. 13 show electron micrographs of channels 41, which are inserted into a borosilicate glass that is marketed under the trade name D263 ® of Schott AG. In this case, different laser parameters are used. In the example of FIG. 12, a burst of 8 individual pulses was used, with the repetition rate of the laser being 100 kHz. In the example shown in FIG. 13, a higher repetition rate of 200 kHz was used, but a burst of only two individual pulses was used in this case. For each channel 5, however, only a single burst was radiated in each case. The channels were then etched in a KOH alkaline solution at 80° C. for a duration of 8 hours. The structure of the channels is similar, whereby, on account of their smaller diameter in comparison to the example of FIG. 10 and FIG. 11, the dome-shaped depressions appear somewhat more bulbous. When other etching media are used, however, the structure approaches that of FIG. 10 and FIG. 11.

Yet another glass from the class of low-alkali silicate glasses that is well suited for the production of a microfluidic cell 1 according to the invention is an alkali-free aluminosilicate glass. Preferred here is a glass with the following composition:

| Composition | (wt %) |
|---|---|
| SiO₂ | 50-75 |
| Al₂O₃ | 7-25 |
| B₂O₃ | 0-20 |
| Li₂O + Na₂O + K₂O | 0-0.1 |
| MgO + CaO + SrO + BaO + ZnO | 5-25 |
| TiO₂ + ZrO₂ | 0-10 |
| P₂O₅ | 0-5 |

In general, it is favorable, without any limitation to the above-mentioned compositions, to use glasses with basicities in the range of 0.45 to 0.55, preferably in the range of 0.48 to 0.54. This makes the glasses especially suitable for a slow, controlled etching using basic etching media, whereby, however, an etching with acidic etching media is also still possible. This glass offers itself then for use in each case not only for the glass element 3, but also for the glass parts 5, 7.

In accordance with yet another embodiment of the invention, a glass with a very low auto-fluorescence is used. The glass can be used for the glass element 3 and/or for at least one of the glass parts 5, 7, preferably for all of these component parts of the microfluidic cell. The intensity of the auto-fluorescence is influenced by the optical basicity. A low optical basicity is associated, in general, with a reduced fluorescence, which is of advantage for biotechnological applications of the microfluidic cell. For instance, the fluorescence markers or labels Cy3 and Cy5 are often used for biotechnological applications. These labels fluoresce at wavelengths of 570 nm and 670 nm, at which many glasses also exhibit auto-fluorescence. The auto-fluorescence degrades the signal-to-noise ratio in optical detection processes. A glass used in accordance with one embodiment of the invention for at least one component part of the microfluidic cell has a ratio of auto-fluorescence emission to excitation of less than 1% at 488 nm. For this purpose, the glass has an optical basicity A of less than 0.6, preferably less than 0.55, especially preferred less than 0.53. In particular, optical basicities of less than 0.52, preferably less than 0.51, is used for at least one of the glass component parts, in particular both for the glass element 3 and for the two glass parts 5, 7. In accordance with one embodiment, a glass of low optical basicity and low auto-fluorescence that contains the following glass constituents is used:

| | |
|---|---|
| SiO₂ | >60 to 90 mol % |
| Al₂O₃ | >0 to 15 mol % |
| B₂O₃ | >4 to 25 mol %, |
| | preferably >5 to 25 mol |
| | %, |
| R₂O | >0 to <20 mol % |
| RO | 0 to <20 mol % |

Here, R₂O is the sum of the contents of the alkali oxides Li₂O, Na₂O, and K₂O. RO is the sum of the contents of ZnO and the alkaline-earth oxides MgO, CaO, SrO, and BaO.

In a special embodiment, the glass contains the following glass constituents:

| | |
|---|---|
| SiO₂ | >80 to <85 mol % |
| Al₂O₃ | >0.5 to <3 mol % |
| B₂O₃ | >8 to 15 mol % |
| R₂O | >0 to <5 mol % |
| RO | 0 to <5 mol % |

In accordance with yet another enhancement of the embodiment with a glass of low auto-fluorescence and low optical basicity, for the quantitative ratio x_{B3+}/x_{Al3+}, the molar contents of boron to aluminum are

$$\frac{{x}_{B 3 +}}{{x}_{A l 3 +}} \geq 7.5 ,$$

preferably

$$\frac{{x}_{B 3 +}}{{x}_{A l 3 +}} \geq 10.$$

On the other hand, the ratio is preferably

$$\frac{{x}_{B 3 +}}{{x}_{A l 3 +}} \leq 25 ,$$

in particular

$$\frac{{x}_{B 3 +}}{{x}_{A l 3 +}} \leq 20 , or \frac{{x}_{B 3 +}}{{x}_{A l 3 +}} \leq 15.$$

Some components of glasses also have a negative influence on the UV transmission. For especially suitable glasses, the contents of these components are limited. Thus, in accordance with yet another alternative or additional embodiment of the invention, the contents of SnO₂, Sb₂O₃, CeO₂, TiO₂, and/or Fe₂O₃ are each in the range of 0 to 0.5 mol %, preferably less than 0.01 mol %.

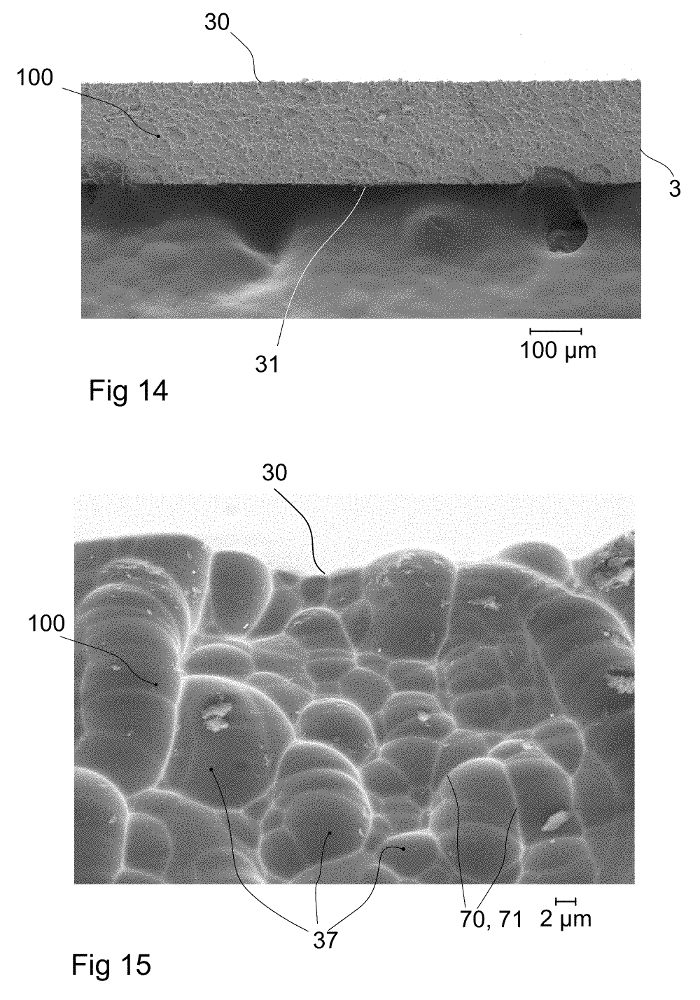

FIG. 14 and FIG. 15 show two additional electron micrographs of the edge 100 of a glass element 3. In this case, FIG. 14 shows the edge 100 in full width of the glass element 3. FIG. 15 shows the edge 100 in high magnification at the transition to one of the side faces 30. The edge 100 was produced as described above in that, during etching, the channels are widened to such an extent that they combine and form a continuous edge, so that a part of the glass element 3 can be released. In the course of the etching, the channels 37* are flattened, so that an essentially flat edge 100 is obtained, which has a plurality of rounded, dome-shaped depressions 37 that border one another. This example shows that the feature of the dome-shaped depressions is independent of the feature of the channels 41 extending transversely to the edge, and an embodiment without such channels 41 can also be realized.

FIG. 15 shows that the depressions 37 here are also separated by ridges 70, which form roughly polygonal boundary lines 71. What is noticeable in the image of FIG. 14, in particular, is that the edge 100 is rectilinear in the direction perpendicular to the side faces 30, 31 and also extends essentially perpendicularly to the side faces. Likewise, the transition from the edge 100 to the side faces 30, 31 is also practically not rounded. The form of this edge 100, as is suitable, in particular, also for the crosspieces 19 between the openings 10, can be characterized, as follows by the above-mentioned properties. The inclination or the angle of the edge surface 100 to the bordering side face 30, 31 is at least 85° in the half of the edge surface that borders the side face. Accordingly, the edge surface extends essentially at a right angle to the side faces 30, 31, with a deviation of at most 5° from a right angle.

As can be seen further in the example of FIG. 15, the transition region in which the inclination of the edge 100 transitions to the bordering side face 30 is thin and is in the order of magnitude of the extension of the dome-shaped depressions 37. In accordance with an enhancement, it is therefore provided that the mean edge radius at the transition from the side face 30, 31 to the edge 100, which is directed essentially perpendicular to the side face 30, 31, is at most 10 micrometers.

Owing to the high stability and strength of the edges of an opening 10 in the glass element 3 that are produced in accordance with the invention, the invention is especially suitable for complex and fragile structures that cannot be produced using other methods. Symmetrical sections with thin and/or long crosspieces are also included here. It was also found, however, that the stability of the glass element 3 is greatly dependent on the geometry. More precisely, it was found that it is favorable for a structure that is held in openings in the glass element by one crosspiece or by a plurality of crosspieces to comply with a specific geometric specification. This specification ensures an adequate stability and handling. Provided in particular, for this purpose, is a glass element 3 that has at least two openings 10 in such a way that, between the openings 10, a structure with at least one crosspiece 19 is formed. In this case, the structure can be assigned a parameter G, which is given by the following relation:

$$G = \frac{{l}_{1}^{2}}{{l}_{2} \cdot b \cdot \sqrt[3]{h} \cdot N}$$

Glass elements 3 according to the invention in microfluidic cells can further be created here with good mechanical stability when the parameter G is at least 10 mm^{-1/3}, preferably at least 50 mm^{-1/3,} especially preferred at least 100 mm^{-1/3}. Conversely, it is sufficient when the parameter is at most 400 mm^{-1/3}, preferably at most 300 mm^{-1/3}, and especially preferred at most 200 mm^{-1/3}.

The variable h in the above relation refers to the thickness of the glass element 3, that is, a thickness of at most 300 micrometers.

For clarification of the parameters of the relation, FIG. 16 shows a glass element 3 that has a simple structure, which, in this case, comprises only one crosspiece 19, which extends between two openings 10.

In the above relation, l₁ refers to the longest edge length between two adjacent contact points or contact regions 44, which lie along the edge of the structure, of one crosspiece or of two different crosspieces 19 and the glass element 3. This measure thus refers to the arc length of the longest edge between two adjacent contact regions 44. Depending on the shaping, the edges 46, 47 of the crosspiece 19 can have different lengths, as also shown in the example of FIG. 16. In the example shown, the edge 46 has a greater length than the edge 47. The parameter 11 here is thus the arc length of this edge 46. The contact regions 44 are the transition regions of the glass at which the crosspiece 19 transitions into the glass surrounding the openings 10 or into the base 43. A contact region 44 is defined here as a circularly shaped region with a diameter of 1 mm, which is positioned at the crosspiece 19 in such a way that the edge thereof touches both edges of the crosspiece 19, that is, also the edges of both openings 10. In this case, for calculation of the parameter G, it is possible to determine the position of the imaginary contact regions 44 by shifting the circularly shaped region from the base 43 in the direction to the crosspiece 19. The position is reached when the region just still fits completely on the glass and the edge thereof touches the edges of the openings 10. As a consequence thereof, this relation and the geometry in accordance with the invention apply to crosspieces with a minimum crosspiece width of less than 1 m.

The length 12 refers to the shortest rectilinear separating distance between two contact regions 44 at the ends of the crosspiece 19. For both lengths 11 and 12, the separating distance from edge to edge of the circularly shaped contact regions 44 is decisive. In the case of more than two contact regions 44, the paths of lengths l₁ and l₂ do not necessarily need to extend between the same contact regions 44. The double arrow inscribed in FIG. 16 for identification of the length 12 accordingly ends also at the edges of the contact regions 44.

Finally, the parameter b refers to the smallest separating distance between the openings 10 with respect to one another along the crosspiece 19 or, in other words, the minimum crosspiece width.

A geometry of this kind, as was described above, is advantageous in regard to strength and handling in connection with the formation of the edge in accordance with the invention, that is, with dome-shaped depressions. However, a geometry of this kind can also be used with differently formed edges.

In the illustrated example, only a single crosspiece 19 is present. However, a plurality of structures is also possible, which are supported by more than one crosspiece. In this case, it is important that, for a plurality of crosspieces, the paths l₁ and l₂ can extend between different contact regions 44. For evaluation of the stability of a design, G thus sets the longest possible path between two contact regions l₁ in relation to the shortest possible connection l₂ of two contact points. As stated, these can also be different contact regions. For the number N of contact regions 44, N≥2 fundamentally applies.

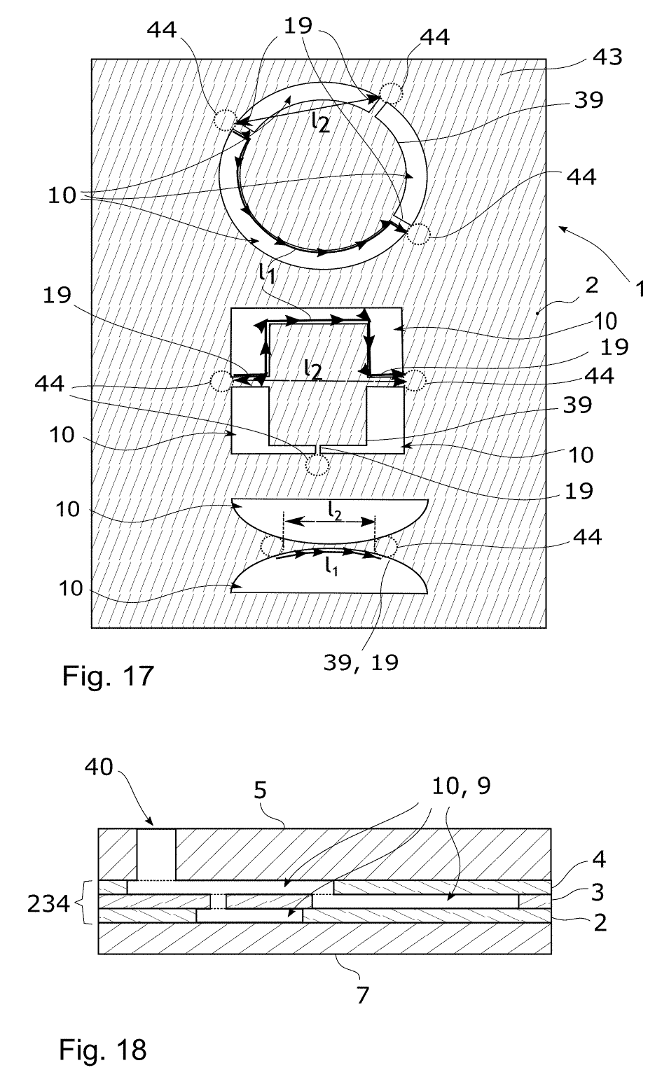

For further clarification, FIG. 17 shows a glass element 3 with three different structures 39, which are formed from glass sections between a plurality of openings 10. The top structure 39 is circular in shape and secured at three crosspieces 19. The structure 39 in the middle of the glass element 3 is likewise secured at three crosspieces 19, but has a rectangular shape. Similar to the example of FIG. 16, the bottommost structure 39 is composed of a single crosspiece 19, which, however, tapers toward the middle. In this case, the crosspiece width tapers from a width of markedly more than 1 mm to a crosspiece width of less than 1 mm in the middle. In accordance therewith, the contact regions 44 for calculation of the parameter G also lie on the crosspiece 19, namely, in such a way that the edges thereof touch the edges of the crosspiece 19 at the point at which the separating distance of the edges drops below 1 m.

On the basis of the two top structures 39, it can be seen that the separating distance 12 and the arc length l₁ between the contact regions 44 at different crosspieces can be calculated. For the parameter G, the longest edge length l₁ between two contact points 44 that lie adjacently along the edge of the structure is decisive. This is inscribed for both structures 39 in each case. In particular, in the example of the topmost circularly shaped structure 39, this results in a shortest separating distance l₂ between two contact regions 44 and a longest edge length l₁ between two other adjacent contact regions 44.

In accordance therewith, in one embodiment of the invention, also regardless of the morphology of the edges, a microfluidic cell 1 having a plate-shaped glass element 3 with a thickness of at most 700 micrometers, preferably at most 300 micrometers, and two opposite-lying side faces 30, 31 is provided, whereby, in the glass element 3, at least two openings 10 are inserted in such a way that the region of the glass element 3 between the openings forms a structure 39 having at least one crosspiece 19, the minimum width of which is less than 1 mm, whereby, for the structure, a parameter G that is specified by the above-given relation is defined, where the parameter G has a value of at least 10 mm^{-1/3} and of at most 400 mm^{-1/3}, where l₁ is the longest edge length between two adjacent contact regions 44 along the edge of one of the openings 13 and l₂ is the length of the shortest possible rectilinear connection between two contact regions 44, and whereby a contact region 44 of a crosspiece 19 is defined in each case as a circularly shaped region of the glass element 3 with a diameter of 1 m, which is arranged at the crosspiece 19 in such a way that the edge thereof touches the edges of both openings 10, the intermediate region of which forms the crosspiece 19, at least at one point in each case, and where b is the minimum crosspiece width, h is the thickness of the glass element 1, and N is the number of contact regions 44. For this embodiment, crosspieces with a minimum width of not less than 300 μm are preferred.

In the above-described exemplary embodiments of the invention, the microfluidic cell comprises a sandwich structure with three levels, namely, the glass parts 5, 7 and the interposed glass element 3. The terms “glass element,” on the one hand, and “glass part,” on the other hand, are chosen in the sense of the description solely to make a simple distinction between the different layers of the sandwich structure. One of the glass parts, such as, for example, the glass part 5, can then, for its part, be designed, in turn, as another glass element 3 with at least one opening 10, which is sealed by another glass part with the formation of a cavity, whereby the other glass part, in turn, can also be another glass element 3 structured with an opening, etc. If, in the above description, the outer glass elements are identified as the glass parts 5, 7 a microfluidic cell 1 with a multilayer structure is obtained. The example of FIG. 18 shows such a microfluidic cell 1. Here, the microfluidic cell 1 comprises three glass elements 2, 3, 4 with openings 10, which are sealed by the other elements and form cavities 9. The glass elements 2, 3, 4 form a stack 234. Two glass parts 5, 7 form the bottom and the cover of the microfluidic cell 1. As in the example of FIG. 1 to FIG. 3, a filling opening 40 is provided in a glass part 5. Preferably, all parts, that is, the glass elements 2, 3, 4 and the sealing glass parts 5, 7, are adhesively bonded to each other, whereby, in accordance with the invention, the respective adhesive layers have regions free of adhesive around the openings 10. As illustrated, it is appropriate when the cavities in the individual glass elements 2, 3, 4 communicate with one another. In accordance with one embodiment, at least a portion of the cavities forms a multilayer arrangement of communicating channels. In the simplest case, the connections between the cavities 9 are generally formed, without any limitation to the specific example, by overlapping the openings 10 of different glass elements 2, 3, 4.

In accordance with one embodiment of the invention, there is thus provided a microfluidic cell 1 that has a stack 234 with at least two disc-shaped glass elements 2, 3, 4 attached to each other as well as two glass parts 5, 7, which are attached to the stack 234 and the stack 234 is arranged between them, whereby the glass elements 2, 3, 4 each have at least one, preferably elongated opening 10, which is sealed by being attached to the bordering glass elements 2, 3,4 or glass parts 5, 7 and thereby forms a cavity 9, which is suitable for the conveyance of fluids. Preferably, as stated, the cavities 9 in the various glass elements communicate with one another. Furthermore, the attachment of glass elements 2, 3, 4 and glass parts 5, 7 is produced, as discussed, through adhesive layers 15, which leave free the openings 10. Furthermore, it is preferred that the openings 10 are produced by the method explained here by introducing filament-shaped damage insertions and etching them to create channels 41, so that the edges 100 of the openings have dome-shaped depressions.

In the embodiments of the invention presented here, the structuring of the glass elements 2, 3, 4 and the glass parts 5, 7 are made in the form of openings, which pass through the respective glass element or glass part. However, it is also possible, by using the above-described laser-assisted etching method, to produce depressions or recesses that are open on one side. Such structures can be combined with the openings 10 or 40 in an advantageous way in order to produce fluid-carrying arrangements in the microfluidic cell 1. In general, without any limitation to the specific examples described here, it is therefore provided in one embodiment of the invention that a glass element 2, 3, 4 and/or glass part has a recess or depression that is open on one side, which is a component part of a structure that is suitable for the conveyance of fluids and, in particular, is a component part of cavities 9 formed with an opening 10 in the glass element 3 or communicates with the cavity 9.

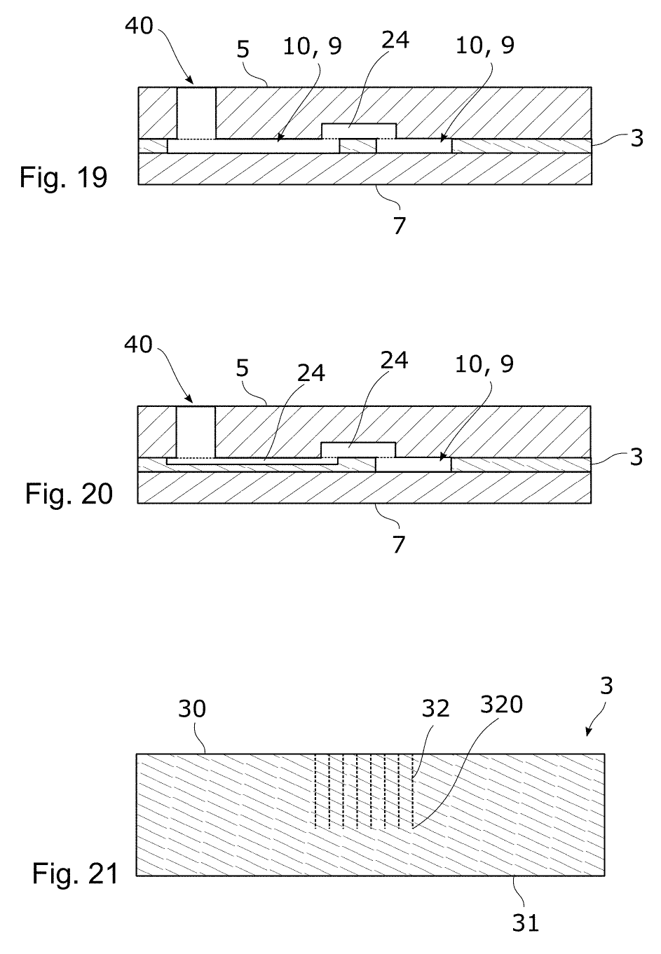

FIG. 19 shows an example of such a microfluidic cell 1. In this example, the glass element 3 has two adjacently lying openings 10, which are sealed by the glass part 5, so that cavities 9 are formed. The glass part 5 has a recess 24, which is arranged in such a way that it connects the two cavities 9, so that the two cavities 9 communicate via the recess 24.

FIG. 20 is a variant in which a recess 24 is inserted into the glass element 3 arranged between the glass parts 5, 7. The recess 24 forms, for example, a channel for the connection of a cavity 9 to the filling opening 40.

The method for producing such a depression or recess 24 is based preferably on a variant of the laser-based method explained above, in which filament-shaped damage insertions introduced by an ultrashort-pulse laser are widened by etching. Without any limitation to the illustrated examples, the method is generally based on the fact that the laser beam 27 of an ultrashort-pulse laser 29 is directed onto one of the side faces 30, 31 of the glass element 3 or the glass parts 5, 7 and concentrated using a focusing optics 23 to form an elongated focus in the glass, wherein, through the irradiated energy of the laser beam 27, filament-shaped damage insertions 32 are produced in the volume of the glass, the longitudinal direction of which extends transversely to the side face 30, 31, in particular perpendicularly to the side face 30, 31, of the glass element 3 or the glass parts 5, 7, and, for the creation of filament-shaped damage by the ultrashort-pulse laser 29, one pulse or a pulse packet containing at least two laser pulses in succession is irradiated, wherein the laser beam 27 is irradiated in such a way that one end of the elongated focus lies inside the glass, so that the filament-shaped damage 32 also terminates in the glass, but extends up to a side face 31, 32; and whereby, after the insertion of the filament-shaped damage 32, the glass is exposed to an etching medium, which removes the glass of the glass element 3 at a removal rate of preferably less than 8 μm per hour, and widens the filament-shaped damage 32 to form a channel 41, so that, on account of the filament-shaped damage 32 ending in the glass, the channels 41 likewise end in the glass and are sealed on one side, whereby the channels 41 are joined laterally during the etching, so that a recess 24 is produced in the glass. The lateral delimitation of the recess is accordingly defined, as in the embodiment with the creation of an opening 10, by the path of the adjacently lying points of impingement of the laser beam. The method is suitable especially for recesses with a depth of up to 5 mm. The depth can be at least 50 μm, preferably at least 100 μm, especially preferred, at least 200 μm.

FIG. 21 shows a glass element 3 with filament-shaped damage insertions 32 therein in accordance with the embodiment of the invention explained previously. The filament-shaped damage insertions 32 have a length that is less than the thickness of the glass element 3. Consequently, one end 320 of the filament-shaped damage insertions 32 lies in the interior of the glass element 3. The filament-shaped damage insertions 32 are then exposed to the etching medium, this being unusual inasmuch as the etching solution penetrates into the filament-shaped damage insertions 32, which end only on one side at the surface, and can bring about the homogeneous, that is, isotropic widening.

For the creation of recesses or depressions 24 that have only one opening to one of the side faces 30, 31 of the glass element 3 or the glass parts 5, 7, the filament-shaped damage insertions 32 according to one embodiment of the invention are produced in a two-dimensional grid.

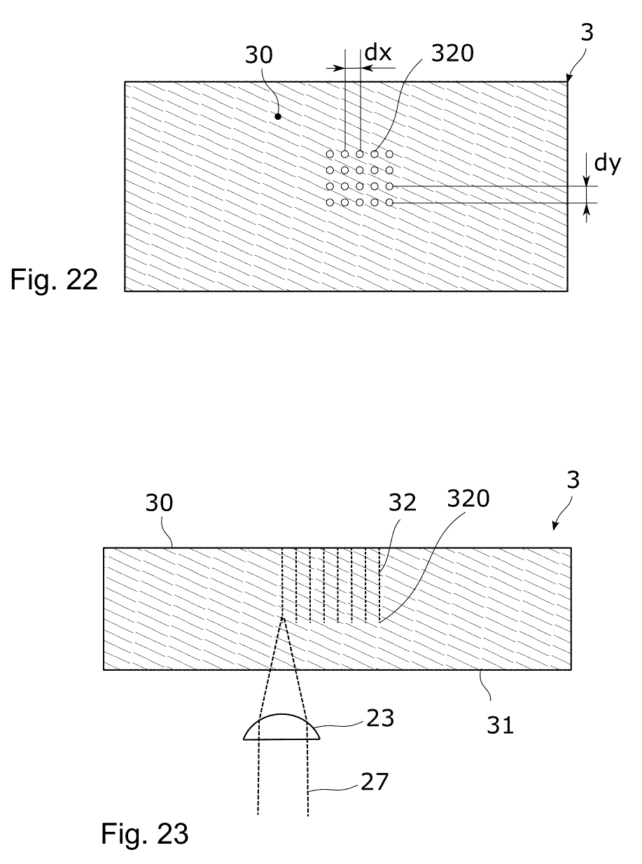

FIG. 22 schematically shows a top view of a side face 30 of a glass element 3 or a glass part 5, 7 with a matrix-shaped or grid-shaped arrangement of filament-shaped damage insertions 32—in the example, a 4×5 arrangement. The inner contour created using this grid-shaped arrangement of the filament-shaped damage insertions 32 after the etching process is accordingly of rectangular shape. It is self-evident to the person skilled in the art that, depending on the arrangement of the filament-shaped damage insertions 32 on the side face of the substrate, various geometric figures can be created, such as, for example, also recesses 24 that generally have a polygonal shape—for example, a triangular shape—or a circular basic shape as well as also free-form surfaces. In FIG. 22, the separating distance between two adjacent filament-shaped damage insertions 32 in the two dimensions is specified by dx and, perpendicularly thereto, by dy. In a matrix-shaped arrangement of the filament-shaped damage insertions 32, the separating distances can be identical in these two directions, but need not be, so that the condition dx≠dy is also possible. The grid need not be rectangular or matrix-shaped, either. The locations of the filament-shaped damage insertions can also be displaced row by row, for example, so that a grid with hexagonal or triangular unit cells is formed. In accordance with one embodiment of the invention, one of the separating distances dx or dy is at least 10 μm, preferably at least 20 μm, and the other separating distance is at least 4 μm, preferably at least 5 μm, more preferably at least 10 μm, most especially preferred 20 μm, whereby both separating distances dx, dy can also be identical, of course. Especially for the production of recesses that are open on one side, intrinsically small separating distances of the filament-shaped damage insertions are desirable. However, the damage insertions can also mutually influence one another, because previously inserted damage can interfere with the light propagation when producing an adjacent damage insertion. In general, in one embodiment of the invention, it is provided for this purpose that the separating distance between adjacent filaments is at least 50·R, preferably at least 100·R, where R is the radius of a filament-shaped damage insertion. In general, without any limitation to illustrated examples, it may be further favorable for reducing the mutual influence of the damage insertions when adjacent damage insertions are not made directly in succession. Instead, an intermittent mode can be used, in which, first of all, filament-shaped damage insertions are produced at a first, greater separating distance and, in a further step, additional filament-shaped damage insertions are then made in between the already existing damage insertions 32. In the case of the damage insertions produced later into the intervening spaces, the influence of already existing damage insertions on the light beam can result in a reduced length of the damage insertion. Nonetheless, the tight arrangement of the filament-shaped damage insertions thus obtained then makes possible a rapid exposure of the recess. Under certain circumstances, the sequence of the filament-shaped damage insertions of different length can thereby be seen as a characteristic pattern at the bottom of the etched-out recess. In general, producing filament-shaped damage insertions 32 in a second step, between already existing filament-shaped damages 32, is also utilized advantageously in the embodiment for which an opening 10 is inserted into the glass element 3.

FIG. 23 shows an arrangement for introducing filament-shaped damage insertions that end in the glass. In principle, it is possible to use an apparatus such as that also illustrated in FIG. 5. The focusing optics 23 can then be adjusted in such a way that an end of the elongated focus lies in the glass. It is favorable when, as illustrated, the end of the focus lying in the glass is directed toward the side face 30 on which the laser beam 27 impinges. In other words, the filament-shaped damage 32 is thus inserted in such a way that the end thereof lying in the glass is directed toward the impinging laser beam 27 or onto the focusing optics 23. This configuration is favorable, because, in this case, small filament separating distances can be chosen, because less contamination of the irradiated side results from the laser process.

### LIST OF REFERENCE NUMBERS

| | |
|---|---|
| 1 | microfluidic cell |
| 2, 3, 4 | disc-shaped glass element |
| 5, 7 | glass part |
| 9 | cavity |
| 10 | opening in 3 |
| 11 | edge of 10 |
| 12 | adhesive |
| 13 | left-free region |
| 15 | adhesive layer |
| 16 | edge of 15 |
| 17 | printing apparatus |
| 18 | printing head |
| 19 | crosspiece |
| 20 | computer |
| 21 | laser processing device |
| 23 | focusing optics |
| 24 | recess |
| 27 | laser beam |
| 29 | ultrashort-pulse laser |
| 30, 31 | side faces of 3 |
| 32 | filament-shaped damage insertion |
| 35 | channel |
| 37 | dome-shaped depression |
| 39 | structure with a plurality of openings 10 |
| 40 | opening in 5, 7 |
| 43 | base |
| 41 | channel |
| 44 | contact region |
| 47 | positioning device |
| 48 | positioning marker |
| 45 | computing device |
| 51 | longitudinal direction of 41 |
| 52 | ridge |
| 54 | wall of 41 |
| 70 | ridge |
| 71 | polygonal boundary line |
| 72 | corner of 71 |
| 73 | point of impingement of the laser beam 27 |
| 90 | inner part |
| 91 | part of the wall of 9 formed by 5, 7 |
| 100 | edge of 10 |
| 101 | flat edge section |
| 234 | stack of glass elements 2, 3, 4 |
| 320 | end of 32 |

What is claimed is:

1. A method for the production of a microfluidic cell, comprising:
structuring a glass element that has a thickness of at most 700 micrometers to have an opening that connects two opposite-lying parallel side faces of the glass element; and
attaching a first glass part to a first face of the two side faces and a second glass part to a second face of the two side faces to seal the opening so that a cavity that is enclosed between the two glass parts, wherein the cavity is configured to convey fluids,
wherein the step of attaching at least one of the first and second glass parts comprises using an adhesive in such a manner that the opening is left free of the adhesive.

2. The method of claim 1, wherein the step of using the adhesive comprises applying the adhesive to at least one of the two faces of the glass element so that the opening is left free of adhesive.

3. The method of claim 1, wherein the step of structuring glass element to have the opening comprises structuring an elongated opening so that the cavity is a fluid-carrying channel.

4. The method of claim 3, wherein the step of using the adhesive comprises printing onto at least one of the two side faces, leaving out a region extending over the elongated opening, wherein the region is larger than the opening so that an edge of the adhesive is set back from an edge of the opening.

5. The method of claim 1, wherein the step of using the adhesive comprises applying the adhesive so that an edge of the opening remains free of adhesive.

6. The method of claim 1, wherein the step of structuring glass element to have the opening comprises:
directing a laser beam of an ultrashort-pulse laser onto one of the two side faces and concentrating the laser beam using a focusing optics to form an elongated focus in the glass element so that a filament-shaped damage insertion is produced in the glass element, wherein the filament-shaped damage insertion has a longitudinal direction that extends perpendicularly between the two side faces; and
exposing, after forming the filament-shaped damage insertion, the glass element to an etching medium to remove glass from the glass element at a removal rate of less than 8 μm per hour to widens the filament-shaped damage insertion to form the opening.

7. The method of claim 6, wherein the etching medium inserts rounded dome-shaped depressions in walls of the opening.

8. The method of claim 6, further comprising repeating the step of directing the laser beam to produce a plurality of filament-shaped damage insertions adjacent to one another, wherein the step of exposing the glass element to the etching medium comprises etching the plurality of filament-shaped damage insertions until adjacent insertions are joined together to form the opening.

9. The method of claim 8, wherein ridges remain between the plurality of filament-shaped damage insertions after the exposing step, the ridges extending parallel to the longitudinal direction.

10. The method of claim 1, further comprising:
directing a laser beam of an ultrashort-pulse laser onto one of the two side faces and concentrating the laser beam using a focusing optics to form an elongated focus in the glass element so that a filament-shaped damage insertion is produced in the glass element, wherein the filament-shaped damage insertion has a longitudinal direction that extends perpendicularly from one of the two side faces and terminates in the glass element;
repeating the step of directing the laser beam to produce a plurality of filament-shaped damage insertions adjacent to one another; and
exposing, after forming the plurality of filament-shaped damage insertions, the glass element to an etching medium to remove glass from the glass element at a removal rate of less than 8 μm per hour until adjacent insertions are joined together to form a recess that is sealed on one side by the glass element.

11. The method of claim 10, wherein ridges remain between the plurality of filament-shaped damage insertions after the exposing step, the ridges extending parallel to the longitudinal direction.

12. The method of claim 1, wherein at least one of the first and second glass parts comprises a second opening, wherein the first and second glass parts are attached to the glass element in such a way that the second opening is in fluid communication with the opening.

13. The method of claim 1, wherein the step of structuring the glass element to have the opening comprises structuring to have at least two adjacently extending openings, the at least two openings being separated from each other by a crosspiece, wherein the cross piece has a minimum width of at most 400 μm, and wherein the crosspiece is bonded with the adhesive to the at least one of the first and second glass parts.

14. The method of claim 1, wherein the adhesive is a photocurable adhesive, the step of attaching further comprising irradiating the adhesive through one of the first and second glass parts to harden the adhesive.

15. A microfluidic cell, comprising:
a disc-shaped glass element with a thickness of at most 700 micrometers and an opening that connects two opposite-lying, parallel side faces of the glass element;
a first glass part attached to a first face of the two side faces;
a second glass part attached to a second face of the two side faces;
a cavity defined by the opening being sealed by the first and second glass parts, the cavity being suitable for fluid conveyance; and
dome shaped depressions in at least part of a wall the opening.

16. The microfluidic cell of claim 15, further comprising:
an adhesive attaching at least one of the first and second glass parts to the glass element; and
a region that is left free of the adhesive around the opening so that a part of the cavity is formed by the first and second glass parts.

17. The microfluidic cell of claim 15, wherein the dome shaped depressions have a depth, on average, of less than 5 μm and/or have a transverse measurement, on average, of 5 μm to 20 μm.

18. The microfluidic cell of claim 15, wherein the opening has an edge that comprises a plurality of parallel, adjacently extending, laterally open channels with a ridge that extends parallel to the longitudinal direction between adjacent open channels.

19. The microfluidic cell of claim 15, further comprising a second opening and a crosspiece, the crosspiece being between the opening and the second opening, the crosspiece having a minimum width of less than 1 mm and having a parameter G of at least 10 mm^{-1/3} and of at most 400 mm^{-1/3}, wherein the parameter G is specified by:
$$G = \frac{{l}_{1}^{2}}{{l}_{2} \cdot b \cdot \sqrt[3]{h} \cdot N} ,$$
wherein l₁ is a longest edge length between two adjacent contact regions along an edge of one of the opening and the second opening,
wherein l₂ is a the length of a shortest possible rectilinear connection between the two contact regions,
wherein a contact region is defined as a circularly shaped region of the glass element with a diameter of 1 mm that is arranged at the crosspiece in such a way that the edge touches edges of both the opening and the second opening, an intermediate region of which forms the crosspiece, at least at one point in each case,
wherein b is a minimum crosspiece width,
wherein h is the thickness of the glass element, and
wherein N is a number of the contact regions.

20. The microfluidic cell of claim 15, further comprising a recess in one of the glass element, the first glass part, and the second glass part, wherein the recess is open on one side and is in fluid communication with the cavity.

21. A microfluidic cell, comprising a stack of at least two disc-shaped glass elements that are attached to each other and two glass parts that are attached to the stack and between which the stack is arranged, wherein the glass elements each have an opening that is sealed by attachment of the bordering glass element or the glass parts to form a cavity configured to convey fluids, wherein the openings in the glass elements communicate with one another, and wherein the glass elements and the glass parts are attached to one another by adhesive layers that leave the openings free of adhesive.

22. The microfluidic cell of claim 21, further comprising dome shaped depressions in at least part of a wall the opening and/or an edge of the opening that comprises a plurality of parallel, adjacently extending, laterally open channels with a ridge that extends parallel to the longitudinal direction between adjacent open channels.

23. An intermediate product for producing a microfluidic cell, comprising:
a disc-shaped glass element with a thickness of at most 700 micrometers and an opening that connects two opposite-lying, parallel side faces of the glass element; and
adhesive on each of the two side faces, the opening being free of the adhesive.

24. The intermediate product of claim 23, further comprising dome shaped depressions in at least part of a wall the opening and/or an edge of the opening that comprises a plurality of parallel, adjacently extending, laterally open channels with a ridge that extends parallel to the longitudinal direction between adjacent open channels.
